(19) United States
(12) Patent Application Publication
(10) Pub. No.: US 2013/0158961 A1
(43) Pub. Date: Jun. 20, 2013

(54) CALCULATION APPARATUS AND CALCULATION METHOD OF MAGNETIC FIELD, ELECTRON DENSITY AND ELECTRON TEMPERATURE

(71) Applicant: Japan Atomic Energy Agency, Naka-gun (JP)

(72) Inventor: Ryota IMAZAWA, Naka-shi (JP)

(73) Assignee: JAPAN ATOMIC ENERGY AGENCY, Naka-gun (JP)

(21) Appl. No.: 13/714,751

(22) Filed: Dec. 14, 2012

(30) Foreign Application Priority Data
Dec. 15, 2011 (JP) 2011-274818

(51) Int. Cl. G06F 15/00; G06F 17/50; G01R 29/00; G01K 13/00; G01R 33/12

(52) U.S. Cl. CPC G06F 15/00; G01K 13/00; G01R 33/1215; G01R 29/00; G06F 17/5009
USPC 703/2; 702/57

(57) ABSTRACT

A calculation apparatus comprising: an acquiring unit to acquire an azimuth and an ellipticity angle of a polarization plane of a laser beam passing through a plasma; and a calculation unit to calculate at least one of a magnetic field profile, an electron density profile and an electron temperature profile in the plasma on the basis of the azimuth and the ellipticity angle.

### CROSS-REFERENCE TO RELATED APPLICATIONS

This application claims the benefit of Japanese Application No. 2011-274818, filed Dec. 15, 2011, in the Japanese Intellectual Property Office, the disclosure of which are incorporated herein by reference.

### BACKGROUND OF THE INVENTION

1. Field of the Invention

The present invention relates to a method of calculating a magnetic field profile, an electron density profile and an electron temperature profile within plasma.

A method of making use of polarization of a laser beam exists as a method of measuring in a non-contact manner the magnetic field profile within the plasma in the nuclear fusion plasma. When a linearly polarized laser beam enters the plasma, a polarization plane thereof rotates and gets ovalized by dint of interaction between the plasma and the laser beam (electromagnetic radiation). In this method, the magnetic field profile is calculated based on an angle of the rotation of the polarization plane of the laser beam. To be specific, a plurality of laser beams enters the plasma, and the magnetic field profile is calculated by estimating the magnetic field profile within the plasma so as to match with the angles of the rotations of the polarization planes thereof.

### DOCUMENT OF PRIOR ART

### Non-Patent Document

2. Description of the Related Art
[Non-Patent document 1] F. HOFMANN, G. TONETTI, “TOKAMAK EQUILIBRIUM RECONSTRUCTION
USING FARADAY ROTATION MEASUREMENTS”, NUCLEAR FUSION, Vol. 28, No. 10, pp. 1871-1878(1988).
[Non-Patent document 2] G. Braithwaite, et al., “JET polari-interferometer”, Rev. Sc. Instrum., Vol. 60, No. 9, pp. 2825-2834(1989).
[Non-Patent document 3] Ch. Fuchs and H. J. Hartfuss, “Cotton-Mouton Effect Measurement in a Plasma at the W7-AS Stellarator”, PHYSICAL REVIEW LETTERS, Vol. 81, No. 8(1998).
[Non-Patent document 4] T. Akiyama, et al. “CO2 laser polarimeter for electron density profile measurement on the Large Helical Device”, Rev. Sci. Instrum., Vol. 74, 2695(2003).
[Non-Patent document 5] R. Imazawa, et al. “A new approach of equilibrium reconstruction for ITER”, Nucl. Fusion, Vol. 51, 113022(2011).

### SUMMARY OF THE INVENTION

Variations (the rotation and the ovalization) of the polarization plane of the laser beam have information on the magnetic field profile and information on the electron density profile on a path of the laser beam, however, it is difficult to simultaneously obtain both of the magnetic field profile and the electron density profile within the plasma form this variation quantity. Therefore, such a necessity exists that any one category of information is acquired by another method. That is, the calculation of the magnetic field profile from a measured value of a polarimeter entails acquiring beforehand the electron density profile within the plasma by an electron density measuring apparatus (an interferometer, a reflectometer, a Thomson scattering diagnostics, etc). This example is given in Non-Patent document 1 and Non-Patent document 2. On the other hand, the calculation of the electron density profile from the measured value of the polarimeter entails acquiring beforehand the magnetic field profile within the plasma. This example is given in Non-Patent document 4. Each of Non-Patent document 2 and Non-Patent document 3 is what measures a linear integral quantity of the electron density on the measurement line of sight from the measured value of the polarimeter in a way that makes use of the magnetic field profile acquired beforehand.

A contribution of the electron temperature (relativistic effect) was small in terms of interaction between the plasma and the laser beam (electromagnetic radiation) and had been therefore ignored so far. The relativistic effect cannot, however, be ignored in a high-temperature plasma in which the nuclear fusion reaction occurs. Namely, on the occasion of obtaining the magnetic field profile and the electron density profile from the measured values of the polarimeter, it is required that the relativistic effect is taken into consideration, and there is a necessity for previously obtaining the electron temperature profile by an electron temperature measuring apparatus (a Thomson scattering diagnostics, an electron cyclotron emission diagnostics, etc). Non-Patent document 5 is given by way of an example of taking the relativistic effect into consideration when obtaining the magnetic field profile.

Accordingly, the electron density profile is needed for obtaining the magnetic field profile within the plasma, and the magnetic field profile is required for obtaining the electron density profile. Namely, it is difficult to simultaneously obtain the magnetic field profile and the electron density profile within the plasma. Then, the electron temperature profile is further needed for taking account of the relativistic effect in the high-temperature plasma.

It is an object of the present invention to identify the physical quantity within the plasma containing the magnetic field profile, the electron density profile and the electron temperature profile from the measured values of the polarimeter even in such a case that the magnetic field profile, the electron density profile and the electron temperature profile within the plasma are unknown.

The present invention adopts the following means in order to solve the problems given above.

Namely, one aspect of the present invention is a calculation apparatus including: an acquiring unit to acquire an azimuth and an ellipticity angle of a polarization plane of a laser beam passing through a plasma; and a calculation unit to calculate at least one of a magnetic field profile, an electron density profile and an electron temperature profile in the plasma on the basis of the azimuth and the ellipticity angle.

Another aspect of the present invention is a calculation apparatus including: an acquiring unit to acquire an azimuth and an ellipticity angle of a polarization plane of a laser beam passing through a plasma; and a calculation unit to simulate the azimuth and the ellipticity angle of the polarization plane of the laser beam passing through the plasma on the basis of a predetermined mathematical model containing a predetermined parameter and to calculate at least one of a magnetic field profile, an electron density profile and an electron temperature profile in the plasma on the basis of a value of the parameter when an index value is smaller than a predetermined value by repeatedly changing the value of the parameter till the index value calculated based on the azimuth and the ellipticity angle and also the azimuth and the ellipticity angle acquired by the acquiring unit becomes smaller than the predetermined value.

The aspect of the disclosure may be realized in such a way that a program is executed by an information processing apparatus. To be specific, the configuration of the disclosure can be specified by way of a program for making an information processing apparatus execute processes carried out by the respective means in the aspects given above, or by way of a recording medium recorded with this program. Further, the configuration of the disclosure may also be specified as a method by which the information processing apparatus executes the processes carried out by the respective means described above.

According to the present invention, it is feasible to identify the physical quantity within the plasma containing the magnetic field profile, the electron density profile and the electron temperature profile even in such a case that both of the magnetic field profile and the electron density profile within the plasma are unknown.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a view illustrating an example of an ellipticity, an ellipticity angle and an azimuth with respect to a general ellipse.

FIG. 2 is a diagram illustrating an example of a calculation apparatus in the embodiment.

FIG. 3 is a diagram illustrating an example of an information processing apparatus.

FIG. 4 is a diagram illustrating an example of an operation flow of the calculation apparatus.

FIG. 5 is a diagram illustrating a specific example (magnetic field profile) of a calculation result by the calculation apparatus in the embodiment.

FIG. 6 is a diagram illustrating a specific example (electron density profile) of a calculation result by the calculation apparatus in the embodiment.

FIG. 7 is a diagram illustrating a specific example (electron temperature profile) of a calculation result by the calculation apparatus in the embodiment.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

An embodiment will hereinafter be described with reference to the drawings. A configuration in the embodiment is an exemplification, and the configuration of the disclosure is not limited to the specific configuration of the embodiment of the disclosure. The specific configuration corresponding to the embodiment may be properly adopted on the occasion of embodying the configuration of the disclosure.

(Outline of Function)

A calculation apparatus in the embodiment calculates a magnetic field profile, an electron density profile and an electron temperature profile within a plasma on the basis of polarization of a laser due to interaction between linearly polarized laser beams incident on an interior of the plasma and the plasma. Herein, the plasma is confined within a predetermined area. The laser beams enter the plasma from a predetermined position (which is termed a start point) of a border of the predetermined area of the plasma and exit from a predetermined position (which is termed an end point) of the border of the predetermined area of the plasma, which position is different from the start point. A straight line passing through the start point and the end point of the laser beam itself is also referred to as a line of sight. Further, the laser beam incident upon the plasma is also referred to as the line of sight as the case may be. A plurality of lines of sight having different start points and different end points can be set for one plasma. A polarimeter receives the incidence of the linearly polarized laser beam from the start point and detects the laser beam polarized at the end point. The calculation apparatus in the embodiment calculates the magnetic field profile within the plasma, which is confined in the predetermined area.

When the linearly polarized laser beam enters the plasma, the laser beam becomes an elliptically polarized light beam due to the interaction between the plasma and an electromagnetic wave. The calculation apparatus in the embodiment calculates the magnetic field profile, the electron density profile and the electron temperature profile by use of an azimuth and an ellipticity angle of the elliptically polarized light beam of the laser, which passes through the plasma. The polarimeter can measure the azimuth and the ellipticity angle of the elliptically polarized light beam of the laser.

On the assumption of a Cartesian coordinate system xyz in which a z-direction is defined as a laser beam propagating direction, an angle made by the x-axis and a direction of a major axis of the ellipse of the elliptically polarized light beam is referred to as the azimuth. The x-axis is taken along a direction of a toroidal magnetic field in a nuclear fusion apparatus. A ratio of a length b of the major axis to a length a of a minor axis of the ellipse of the elliptically polarized light beam, is referred to as the ellipticity. Further, the ellipticity is a tangent of the ellipticity angle. Namely, let E be the ellipticity and n be the ellipticity angle, and the following relation is given.

$$E = tan ɛ = \frac{a}{b} \qquad [ Mathematical Expression 1 ]$$

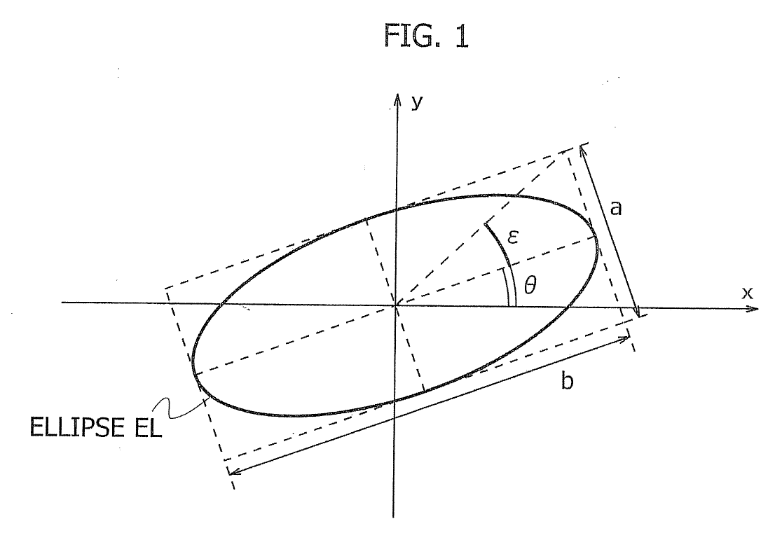

FIG. 1 is a view illustrating an example of the ellipticity, the ellipticity angle and the azimuth with respect to a general ellipse. In the example of FIG. 1, an ellipse EL has the length b of the major axis, the length a of the minor axis and the ellipticity angle ε. Further, θ is given as the azimuth.

(Example of Configuration)

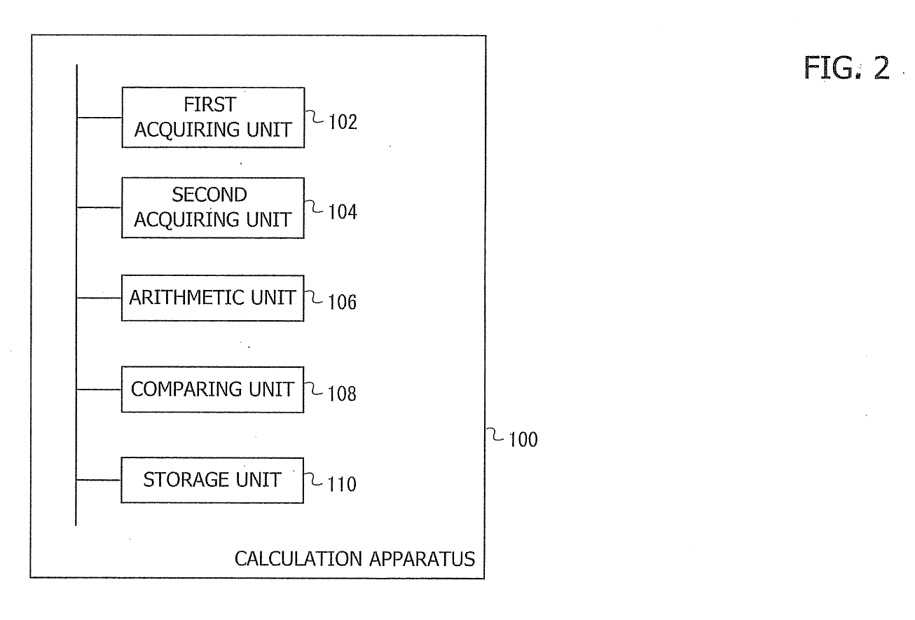

FIG. 2 is a diagram illustrating an example of the calculation apparatus in the embodiment. A calculation apparatus 100 includes a first acquiring unit 102, a second acquiring unit 104, an arithmetic unit 106, a comparing unit 108 and a storage unit 110. Any two or more function units of these function units may operate as one function unit. For example, the first acquiring unit 102 and the second acquiring unit 104 may operate as one acquiring unit. Furthermore, one function unit of these function units may operate as a plurality of function units.

The first acquiring unit 102 acquires the azimuth and the ellipticity angle of the polarized light beam of the laser that are measured by the polarimeter etc, position information on the start point and the end point of the laser beam and position information (information on a shape of the plasma area) on a boarder of the plasma area, which are stored in the storage unit 110. These items of information may also be acquired directly from an external device (e.g., the polarimeter etc). These items of information can be used in the arithmetic unit 106 and the comparing unit 108.

The second acquiring unit 104 acquires a mathematical model stored in the storage unit 110. The acquired mathematical model is used in the arithmetic unit 106.

The arithmetic unit 106 calculates the azimuth and the ellipticity angle of the polarized light beam of the laser on the basis of the position information on the border of the plasma area that is acquired by the first acquiring unit 102 and the mathematical model acquired by the second acquiring unit 104. The arithmetic unit 106 repeats the arithmetic operations (calculations) in a way that changes free parameters in the mathematical model on the basis of a comparative result of the comparing unit 108.

The comparing unit 108 compares a physical quantity calculated from the mathematical model with a physical quantity acquired by the first acquiring unit 102. If a difference between these physical quantities is equal to or larger than a predetermined value, the arithmetic unit 106 repeats calculating the physical quantities.

The storage unit 110 gets stored with the azimuth and the ellipticity angle of the polarized light beam of the laser that are measured by the polarimeter etc, the position information on the start point and the end point of the laser beam and a wavelength of the laser beam in the way of being associated with each other. If the laser beam for use has one type wavelength, the wavelength of the laser beam may be independently stored. Further, the storage unit 110 gets stored with the position information on the border of the plasma area. The position information on the boarder is given as, e.g., an aggregation of faces which cover the shape of the plasma area. Moreover, if the shape of the plasma area does not depend on the rotating direction in a cylindrical coordinate system, the position information on the border of the plasma area may also be given as a closed curve on the RZ plane in the cylindrical coordinate system. Further, the closed curve may also be given as a relational expression of 2 coordinates (R, Z). The relational expression of the 2 coordinates is exemplified such as (R−a)²+Z²=b² (a and b are positive constants). Furthermore, the closed curve may also be given as a closed curve (polygon) formed by an aggregation of coordinates of a plurality of points and line segment connecting these points. In a tokamak plasma, for example, the plasma is confined within a vacuum container taking the doughnut shape.

The storage unit 110 is stored with the mathematical model for calculating a predetermined physical quantity from one or a plurality of physical quantities. The mathematical model is defined an equation etc representing a function of another physical quantity for calculating the predetermined physical quantity and a relation between the physical quantity and the physical quantity. The mathematical model serves to calculate the predetermined physical quantity from one or the plurality of physical quantities. The storage unit 110 is stored with the mathematical model as functions of the plurality of physical quantities, a coefficient matrix of a simultaneous equation representing a relation between the plural physical quantities, a coefficient matrix of a simultaneous equation representing a relation in time differential value and space differential value between the plural physical quantities, and a coefficient given when the predetermined physical quantity is expressed by a primary expression and a polynomial expression of one or more other physical quantities. Further, the storage unit 110 is stored with the mathematical model as a differential equation or a partial differential equation representing the relation between plural physical quantities. The differential equation etc may be stored in the storage unit 110 as an algebraic equation after undergoing Fourier transform, wavelet transform and Laplace transform. The physical quantity to be sought is acquired by substituting the predetermined physical quantity into the relevant function etc. The mathematical model stored in the storage unit 110 is exemplified such as the GS (Grad-Shafranov) equation and the Strokes equation. Further, the mathematical model stored in the storage unit 110 is exemplified by a relation between a toroidal current density, an electron density, an electron temperature and a poloidal flux.

The calculation apparatus 100 can be realized by use of a general-purpose computer such as a personal computer (PC) and a PDA (Personal Digital Assistant) or a dedicated computer such as a work station (WS) and a server machine. Further, the calculation apparatus 100 can be also realized by employing electronic equipment mounted with the computer. Still further, the calculation apparatus 100 can be also realized by using the dedicated computer such a smartphone, a mobile phone and a car navigation system or the general-purpose computer or the electronic equipment mounted with the computer.

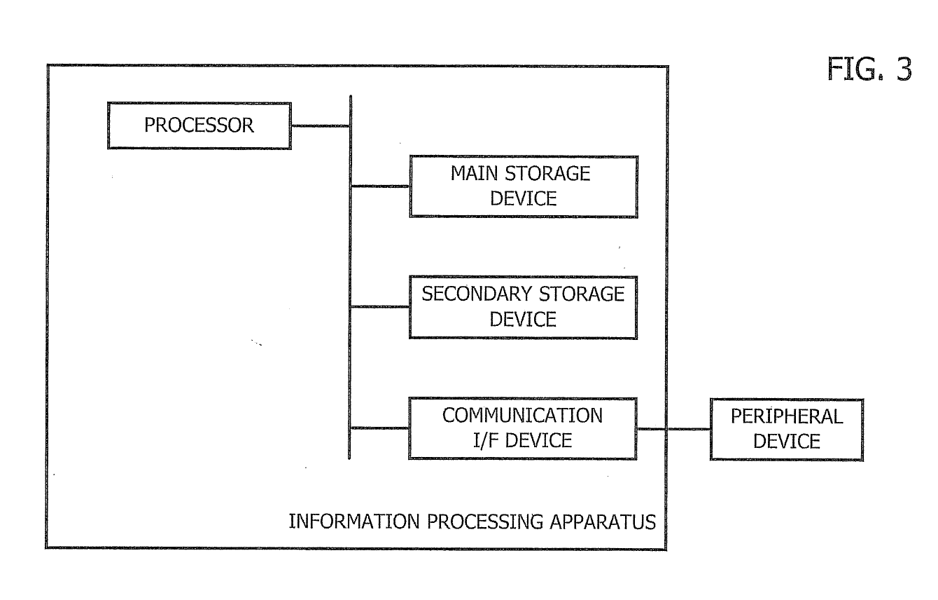

FIG. 3 is a diagram illustrating an example of an information processing apparatus. The computer, i.e., the information processing apparatus, includes a processor, a main storage device and an interface device with peripheral devices such as a secondary storage device and a communication interface device. The main storage device and the secondary storage device are each defined as a non-transitory computer-readable recording medium.

The processor loads the program stored on the recording medium into a work area of the main storage device and thus executes the program, and the peripheral devices are controlled through the execution of the program, whereby the computer can realize the function matching with a predetermined purpose.

The processor is, e.g., a CPU (Central Processing Unit), a GPU (Graphical Processing Unit) and a DSP (Digital Signal Processor). The main storage device includes, for example, a RAM (Random Access Memory) and a ROM (Read Only Memory).

The secondary storage device is, for instance, an EPROM (Erasable Programmable ROM) and a hard disk drive (HDD). Further, the secondary storage device can include a removable medium, i.e., a portable recording medium. The removable medium is a disk recording medium such as a USB (Universal Serial Bus) memory or a CD (Compact Disk) and a DVD (Digital Versatile Disk).

The communication interface (I/F) device is, e.g. a LAN (Local Area Network) interface board and a wireless communication circuit for wireless communications.

The peripheral device includes, in addition to the secondary storage device and the communication interface device, an input device such as a keyboard and a pointing device, and an output device such as a display device and a printer. Moreover, the input device can include a video/image input device such as a camera and a voice input device such as a microphone. Moreover, the output device can include a voice output device such as a loudspeaker.

The processor loads the program stored in the secondary storage device and loads the program into the main storage device, whereby the computer realizing the functions as the first acquiring unit 102, the second acquiring unit 104, the arithmetic unit 106 and the comparing unit 108. Furthermore, the data used when executing the program can be stored in the main storage device or the secondary storage device. The data used when executing the program may be inputted via a network connected to the communication interface and may also be inputted by a user etc through the input device etc.

The storage unit 110 is realized by, e.g., the main storage device and the secondary storage device.

A series of processes can be, though executed hardwarewise, also executed softwarewise.

Steps of describing the program include, of course, the processes executed in time-series along the described sequence and the processes that are executed in parallel or individually if not necessarily processed in time-series.

### OPERATIONAL EXAMPLE

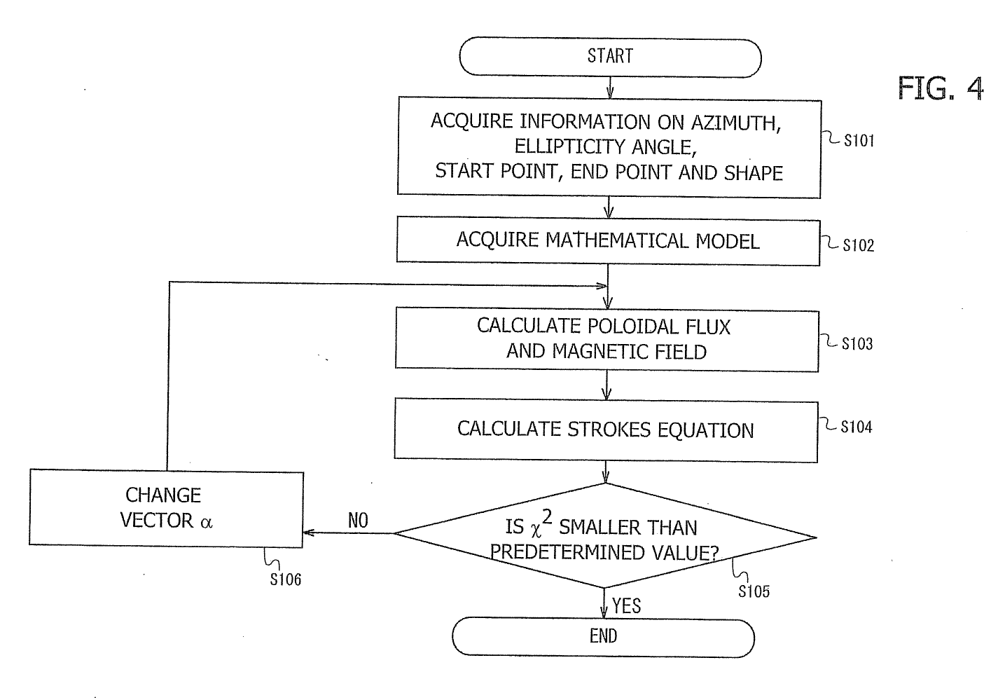

FIG. 4 is a diagram illustrating an example of an operation flow of the calculation apparatus 100.

The first acquiring unit 102 of the calculation apparatus 100 acquires the azimuth and the ellipticity angle of the polarized light beam of the laser that are measured by the polarimeter etc, the position information on the start point and the end point of the laser beam, the wavelength of the laser beam and the position information on the border of the plasma area from the storage unit 110 (S101). The first acquiring unit 102 acquires the azimuths, the ellipticity angles and the position information on the start points and the end points with respect to a plurality of lines of sight. The first acquiring unit 102 acquires the azimuths and the ellipticity angles at the start points and the end points of the respective lines of sight. The azimuth and the ellipticity angle of the polarized light beam of the laser at the start point are acquired as, e.g., the azimuth and the ellipticity angle of the laser beam, which enters the plasma. The first acquiring unit 102 may also acquire the azimuth and the ellipticity angle of the polarized light beam of the laser and the position information on the start point and the end point of the laser beam directly from the polarimeter defined as an external device. The border of the plasma area is also termed an outermost shell magnetic surface (Last Close Flux Surface (LCFS) or separatrix). Herein, it is assumed that the border surface of the plasma area takes a shape not depending on the rotating direction in the cylindrical coordinate system. Namely, the border surface of the plasma area is given by the closed curve on the RZ plane that does not depend on a rotating direction φ in the cylindrical coordinate system. Further, the first acquiring unit 102 acquires vacuum toroidal magnetic field information R₀B_{φ0} (R₀: a position in the radial direction, B_{φ0}: a vacuum toroidal magnetic field in R₀) from the storage unit 110. The vacuum toroidal magnetic field B_{φ} is expressed in the following formula.

$${B}_{φ} = \frac{{R}_{0} {B}_{φ 0}}{R} \qquad [ Mathematical Expression 2 ]$$

The second acquiring unit 104 of the calculation apparatus 100 acquires the mathematical model from the storage unit 110 (S102). Specifically, the second acquiring unit 104 acquires respective formulae for a toroidal current density j_{□□}, an electron density nₑ and an electron temperature Tₑ, the GS equation and the Strokes equation from the storage unit 110.

The arithmetic unit 106 of the calculation apparatus 100 calculates the poloidal flux and the magnetic field on the basis of the information acquired in step S102 (S103). The toroidal current density j_{φ}, the electron density nₑ and the electron temperature Tₑ are expressed as below by way of functions of the poloidal flux ψ. Herein, R is the coordinate in the radial direction. Specific examples of the toroidal current density j_{φ}, the electron density nₑ and the electron temperature Tₑ will be given later on.

$${j}_{φ} = RF ( \overline{ψ} , \vec{a} ) + \frac{G ( \overline{ψ} , \vec{b} )}{R} \\ {n}_{e} = H ( \overline{ψ} , \vec{c} ) \\ {T}_{e} = I ( \overline{ψ} , \vec{d} ) \\ \overline{ψ} \text{:} normalized poloidal flux \qquad [ Mathematical Expression 3 ]$$

Herein, aᵢ (i=1, . . . , NA) (vector a), bᵢ (i, . . . , NB) (vector b) are set as free parameters of the toroidal current density j_{φ}. cᵢ (i=1, . . . , NC) (vector c) is set as a free parameter of the electron density nₑ. dᵢ (i=1, . . . , ND) (vector d) is set as a free parameter of the electron temperature Tₑ. The vector a, the vector b, the vector c and the vector d in combination are also referred to as a vector α(=(a₁ . . . a_{NA} b₁ . . . b_{NB} c₁ . . . c_{NC} d₁ . . . d_{ND})^{t}).

Furthermore, the normalized poloidal flux is defined as follows by use of a poloidal flux ψ_{edge} of the border surface (Last Close Flux Surface (LCFS)) of the plasma area and a poloidal flux ψₐₓ of the magnetic axis.

$$\overline{ψ} = \frac{ψ - {ψ}_{edge}}{{ψ}_{ax} - {ψ}_{edge}} \qquad [ Mathematical Expression 4 ]$$

Moreover, the GS equation is expressed as below, in which R is the coordinate in the radial direction and Z is the coordinate in the vertical direction in the cylindrical coordinate system.

$$R \frac{\partial }{\partial R} ( \frac{1}{R} \frac{\partial ψ}{\partial R} ) + \frac{{\partial }^{2} ψ}{\partial {Z}^{2}} = - 2 π {μ}_{0} {Rj}_{φ} \qquad [ Mathematical Expression 5 ]$$

Herein, μ₀ represents an absolute permeability of vacuum.

The arithmetic unit 106 obtains the poloidal flux ψ on the basis of these formulae. A shape of the LCFS can be used as a border condition.

Further, the arithmetic unit 106 calculates the magnetic field B (B_{R}, B_{D}, B_{Z}) on the basis of the following formula.

$${B}_{R} ( R , Z ) = - \frac{1}{2 π R} \frac{\partial ψ ( R , Z )}{\partial Z} \\ {B}_{φ} ( R , Z ) = \frac{1}{R} \sqrt{{( {R}_{0} {B}_{φ 0} )}^{2} + 2 {μ}_{0} {\int }_{0}^{\overline{ψ} ( R , Z )} G ( \overline{ψ} , \vec{b} ) d \overline{ψ}} \\ {B}_{Z} ( R , Z ) = \frac{1}{2 π R} \frac{\partial ψ ( R , Z )}{\partial R} \qquad [ Mathematical Expression 6 ]$$

Next, the arithmetic unit 106 solves the Strokes equation by using the poloidal flux, the magnetic field, etc that are obtained in step S103 (S104). In the case of assuming the Cartesian coordinate system xyz in which the z-direction is set as the direction of the line of sight of the laser beam, the Strokes equation is expressed as below.

$$\frac{d \vec{s}}{d z} = ( \begin{matrix}{C}_{CM} {λ}^{3} {n}_{e} {B}_{⊥}^{2} cos 2 β ( 1 + \frac{9}{2} \frac{{T}_{e}}{{m}_{e} {c}^{2}} ) \\ - {C}_{CM} {λ}^{3} {n}_{e} {B}_{⊥}^{2} sin 2 β ( 1 + \frac{9}{2} \frac{{T}_{e}}{{m}_{e} {c}^{2}} ) \\ 2 {C}_{FR} {λ}^{2} {n}_{e} {B}_{//} ( 1 - 2 \frac{{T}_{e}}{{m}_{e} {c}^{2}} )\end{matrix} ) \times \vec{s} \qquad [ Mathematical Expression 7 ]$$

Herein, a vector s is the Strokes vector. A symbol B_{∥} represents a z-component of the magnetic field B_{⊥} denotes a component vertical to the z-direction of the magnetic field B, β designates an angle made by B_{⊥} and the y-axis, λ represents a wavelength of the light beam (laser beam), mₑ stands for a mass of the electron, and c represents a speed of light.

Symbols C_{FR} and C_{CM} are constants that are expressed as follows.

$${C}_{FR} = \frac{{e}^{3}}{8 {π}^{2} {ɛ}_{0} {m}_{e}^{2} {c}^{3}} \\ {C}_{CM} = \frac{{e}^{4}}{16 {π}^{3} {ɛ}_{0} {m}_{e}^{3} {c}^{4}} \qquad [ Mathematical Expression 8 ]$$

Herein, e is an elementary charge quantity, and ε₀ is a dielectric constant of the vacuum.

The Strokes vector is expressed as below.

$$\vec{s} = ( \begin{matrix}cos 2 ɛ cos 2 θ \\ cos 2 ɛ sin 2 θ \\ sin 2 ɛ\end{matrix} ) \qquad [ Mathematical Expression 9 ]$$

A symbol θ is the azimuth, and ε is the ellipticity angle. The arithmetic unit 106 calculates the azimuth θ and the ellipticity angle ε per line of sight from this equation.

The comparing unit 108 of the calculation apparatus 100 calculates χ² defined as a cost function of a least-squares method, and determines whether χ² is less than a predetermined value or not (S105). The predetermined value is stored in the storage unit 110. The cost function χ² is expressed, e.g., as follows.

$${χ}^{2} = {\sum }_{k = 1}^{N} \{ {( {θ}_{k}^{E} - {θ}_{k}^{G} )}^{2} + {( {ɛ}_{k}^{E} - {ɛ}_{k}^{G} )}^{2} \} \qquad [ Mathematical Expression 10 ]$$

Herein, θ^{ε}ₖ is the azimuth of a k-th line of sight obtained in step S104, and θ^{G}ₖ is the azimuth of the k-th line of sight obtained in step S101. Further, ε^{ε}ₖ is the ellipticity angle of the k-th line of sight obtained in step S104, and ε^{G}ₖ is the ellipticity angle of the k-th line of sight obtained in step S101. The symbol N represents the number (total number) of the lines of sight. The azimuth and the ellipticity angle used herein are the azimuth and the ellipticity angle in a position on an outgoing side of the laser beam, respectively. The cost function χ² may be normalized. Herein, on the incident side of the laser beam, the azimuth and the ellipticity angle acquired by the first acquiring unit 102 are deemed to be substantially the same as the azimuth and the ellipticity angle calculated by the arithmetic unit 106 in step S104. In the formula of χ², Δθ defined as a difference between the azimuth on the incident side and the azimuth on the outgoing side of the laser beam and Δε defined as a difference between the ellipticity angle on the incident side and the ellipticity angle on the outgoing side of the laser beam, may be used as substitutes for the azimuth θ and the ellipticity angle ε. Another index value may be used as a substitute for χ².

If χ² is equal to or larger than the predetermined value (S105; NO), the processing advances to step S106.

In step S106, the arithmetic unit 106 changes the values of the respective components of the vector α (S106). The arithmetic unit 106 changes the values of the respective components of the vector α so that χ² becomes much smaller. Namely, the arithmetic unit 106 changes the values of the respective components of the vector a so that the azimuth and the ellipticity angle of each line of sight obtained in step S104 converge on the azimuth and the ellipticity angle of each line of sight obtained in step S101.

To be specific, for example, a gradient method is employed. The gradient method defines a non-dimensional parameter qᵢ with respect to a component (which is to be ρᵢ) of the vector a as follows.

$${q}_{i} = \frac{{p}_{i}}{Δ {p}_{i}} \qquad [ Mathematical Expression 11 ]$$

Herein, Δpᵢ is a constant and is a value specified by the user. For example, this constant is given such as Δpᵢ=1 and so on. Next, the gradient vector γ is defined as below. The symbol M is the number of the components of the vector α.

$${γ}_{i} = \frac{\frac{\partial {χ}^{2}}{\partial {q}_{i}}}{\sqrt{{\sum }_{j = 1}^{M} {( \frac{\partial {χ}^{2}}{\partial {q}_{j}} )}^{2}}} \qquad [ Mathematical Expression 12 ]$$

The free parameter is updated in the following formula by use of the gradient vector γ and Δpᵢ.

p′ᵢ=pᵢ−γᵢΔpᵢ [Mathematical Expression 13]

Herein, p′ᵢ is the component of the vector α after being updated (changed).

Moreover, other methods such as the modified Marquardt method and the Gauss-Newton method can be used in place of the gradient method. The arithmetic unit 106, upon changing the vector α, performs calculations from step S103 onward by use of the post-changing vector α.

In step S105, if χ² is smaller than the predetermined value (S105; YES), the calculation apparatus 100 finishes processing. The values of the respective components of the vector α are stored in the storage unit 110. The profiles to be sought are the magnetic field profile, the electron density profile and the electron temperature profile, which are expressed by use of the vector α at this time.

(Specific Example of Toroidal Current Density)

Specific examples of F and G of the toroidal current density j_{□□} are given herein.

$$( Example 1 of {j}_{φ} ) \\ F ( \overline{ψ} , \vec{a} ) = {\sum }_{i} {a}_{i} {\overline{ψ}}^{i} \\ G ( \overline{ψ} , \vec{b} ) = {\sum }_{i} {b}_{i} {\overline{ψ}}^{i} \\ ( Example 2 of {j}_{φ} ) \\ F ( \overline{ψ} , \vec{a} ) = {\sum }_{i} {a}_{i} {\overline{ψ}}^{i} \\ G ( \overline{ψ} , \vec{b} ) = g \frac{d g}{d ψ} , \\ g ( \overline{ψ} , \vec{b} ) = {\sum }_{i} {b}_{i} {\overline{ψ}}^{i} \\ ( Example 3 of {j}_{φ} ) \\ F ( \overline{ψ} , \vec{a} ) = {a}_{1} {\overline{ψ}}^{{a}_{2}} \\ G ( \overline{ψ} , \vec{b} ) = {b}_{1} {\overline{ψ}}^{{b}_{2}} \\ ( Example 4 of {j}_{φ} ) \\ F ( \overline{ψ} , \vec{a} ) = {a}_{1} {\overline{ψ}}^{{a}_{2}} \\ G ( \overline{ψ} , \vec{b} ) = g \frac{d g}{d ψ} , \\ g ( \overline{ψ} , \vec{b} ) = {b}_{1} {\overline{ψ}}^{{b}_{2}} \\ ( Example 5 of {j}_{φ} ) \\ F ( \overline{ψ} , \vec{a} ) = {\sum }_{i} {a}_{i} {\overline{ψ}}^{i} \\ G ( \overline{ψ} , \vec{b} ) = {b}_{1} F ( \overline{ψ} , \vec{a} ) \\ ( Example 6 of {j}_{φ} ) \\ F ( \overline{ψ} , \vec{a} ) = {\{ 1 - {( 1 - \overline{ψ} )}^{{a}_{1}} \}}^{{a}_{2}} \{ 1 - {{a}_{3} ( \frac{\overline{ψ} - {a}_{4}}{1 - {a}_{4}} )}^{2} \} \\ G ( \overline{ψ} , \vec{b} ) = {b}_{1} F ( \overline{ψ} , \vec{a} ) \qquad [ Mathematical Expression 14 ]$$

(Specific Example of Electron Density)

A specific example of the electron density nₑ is given herein.

$$( Example 1 of {n}_{e} ) \\ {n}_{e} = {\sum }_{i} {c}_{i} {\overline{ψ}}^{i - 1} \\ ( Example 2 of {n}_{e} ) \\ {n}_{e} = {c}_{1} + {c}_{2} {\overline{ψ}}^{{c}_{3}} \\ ( Example 3 of {n}_{e} ) \\ {n}_{e} = {c}_{1} + {c}_{2} {\{ 1 - {( 1 - \overline{ψ} )}^{{c}_{3}} \}}^{{c}_{4}} \qquad [ Mathematical Expression 15 ]$$

(Specific Example of Electron Temperature)

A specific example of the electron temperature Tₑ is given herein.

$$( Example 1 of {T}_{e} ) \\ {T}_{e} = {\sum }_{i} {d}_{i} {\overline{ψ}}^{i - 1} \\ ( Example 2 of {T}_{e} ) \\ {T}_{e} = {d}_{1} + {d}_{2} {\overline{ψ}}^{{d}_{3}} \\ ( Example 3 of {T}_{e} ) \\ {T}_{e} = {d}_{1} + {d}_{2} {\{ 1 - {( 1 - \overline{ψ} )}^{{d}_{3}} \}}^{{d}_{4}} \qquad [ Mathematical Expression 16 ]$$

### SPECIFIC EXAMPLE

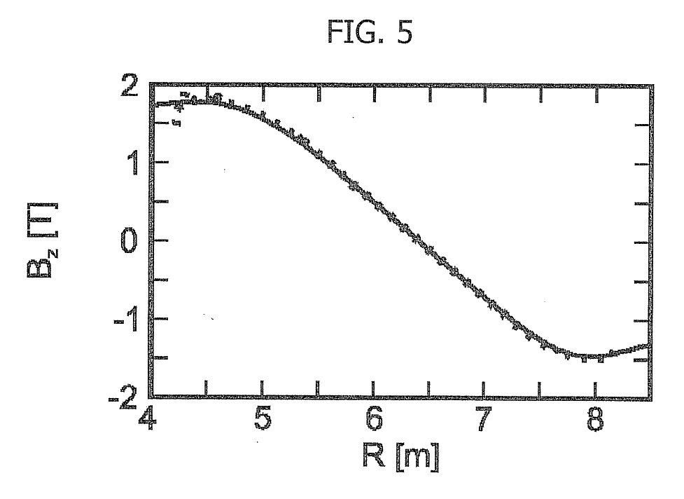

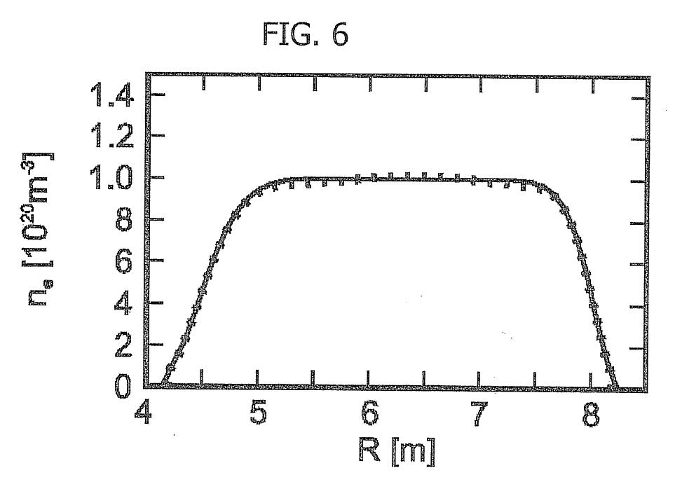

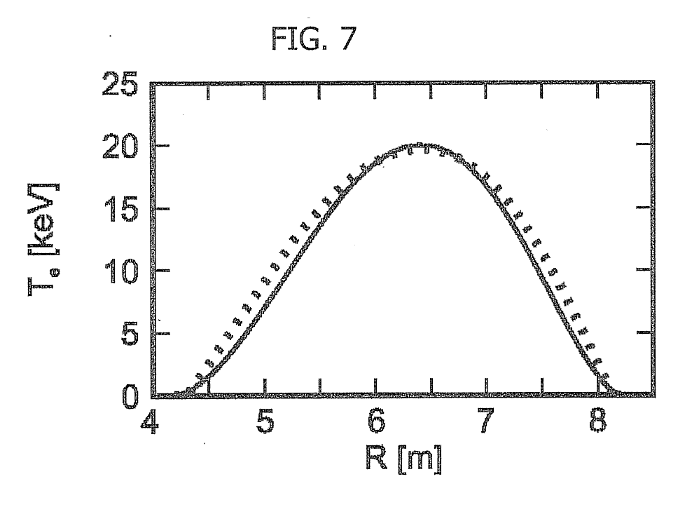

FIGS. 5, 6 and 7 are diagrams illustrating specific examples of calculation results of the calculation apparatus in the embodiment. On the assumption of the tokamak plasma, the calculation apparatus in the embodiment obtains the magnetic field profile, the electron density profile and the electron temperature profile. FIG. 5 is a graph illustrating an example of the magnetic field profile. In the graph of FIG. 5, the axis of abscissas indicates the radial direction in the cylindrical coordinate system, while the axis of ordinates indicates the magnetic field. FIG. 6 is a graph illustrating an example of the electron density profile. In the graph of FIG. 6, the axis of abscissas indicates the radial direction in the cylindrical coordinate system, while the axis of ordinates indicates the electron density. FIG. 7 is a graph illustrating an example of the electron temperature profile. In the graph of FIG. 7, the axis of abscissas indicates the radial direction in the cylindrical coordinate system, while the axis of ordinates indicates the electron temperature. In the graph of each of the drawings, a dotted line indicates the profile of the calculation result given by the calculation apparatus in the embodiment, and a solid line indicates a true profile. In each graph, the profile of the calculation result given by the calculation apparatus in the embodiment is substantially coincident with the true profile.

### Operation and Effect of Embodiment

Only the azimuth has hitherto been focused in the case of estimating the profile of the physical quantity within the plasma from the data of the polarimeter. If using an approximation of the Faraday effect, the azimuth takes a value obtained by linearly integrating a product of the density and the magnetic field component parallel to the line of sight on the line of sight. Accordingly, the electron density profile is calculated from the azimuth on the assumption that the magnetic field profile is already known (e.g., the magnetic field is already known in the helical type nuclear fusion plasma), or alternatively the magnetic field profile is calculated from the azimuth on the assumption that the electron density profile is already known from other types of electron density profile measuring apparatuses (an interferometer, a reflectometer, a Thomson scattering diagnostics, etc). Further, a linear integral quantity of the density on the line of sight has hitherto been acquired by use of the approximation of the Cotton-Mouton effect in a way that employs the ellipticity angle as the data of the polarimeter in order to simply estimate the electron density from the data of the polarimeter.

The calculation apparatus in the embodiment calculates the magnetic field and the electron density profile from the data of the polarimeter (without such a premise that the information of any one of the magnetic field and the electron density is already known). The data of the polarimeter involves using the azimuth and the ellipticity angle, and not the approximations of the Faraday effect and the Cotton-Mouton effect but the Strokes equation is used on the occasion of simulating the azimuth and the ellipticity angle, thereby improving the accuracy. The ellipticity angle depends mainly on the toroidal magnetic field and the electron density, however, the toroidal magnetic field during the generation of the plasma has no large difference from the vacuum toroidal magnetic field, and it is therefore more accurate to estimate the electron density from the ellipticity angle than estimating the density from the azimuth. Hence, the calculation apparatus in the embodiment is capable of simultaneously calculating the magnetic field profile and the electromagnetic density profile without using the measurement results of other electron density measuring apparatuses (the interferometer, the Thomson scattering diagnostics, the reflectometer, etc).

Moreover, the calculation apparatus in the embodiment precisely grasps the electron temperature dependency of the data of the polarimeter by taking into the relativistic effect consideration in the Strokes equation and therefore enables the calculation of the electron temperature profile that could not hitherto be considered. The calculation of the electron temperature profile by the calculation apparatus in the embodiment is preferable in the electron temperature area (equal to or larger than, e.g., 10 keV) in which the influence of the relativistic effect appears.

The calculation apparatus in the embodiment can be applied to whichever plasma state within the plasma if the mathematical model of the plasma exists.

### INDUSTRIAL APPLICABILITY

The calculation apparatus 100 described herein can be applied to, e.g., a tokamak control apparatus. The tokamak control apparatus. In the tokamak control apparatus, the magnetic field profile etc in the plasma is calculated by setting, as a restraint condition, the data measured by the polarimeter etc in a non-contact state with the plasma. If the desired plasma state is different from the calculation result, the plasma state is controlled by employing a coil current, an electromagnetic wave heating apparatus, a neutral particle beam apparatus, etc.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A calculation apparatus comprising:
an acquiring unit to acquire an azimuth and an ellipticity angle of a polarization plane of a laser beam passing through a plasma; and
a calculation unit to calculate at least one of a magnetic field profile, an electron density profile and an electron temperature profile in the plasma on the basis of the azimuth and the ellipticity angle.

2. A calculation apparatus comprising:
an acquiring unit to acquire an azimuth and an ellipticity angle of a polarization plane of a laser beam passing through a plasma; and
a calculation unit to simulate the azimuth and the ellipticity angle of the polarization plane of the laser beam passing through the plasma on the basis of a predetermined mathematical model containing a predetermined parameter and to calculate at least one of a magnetic field profile, an electron density profile and an electron temperature profile in the plasma on the basis of a value of the parameter when an index value is smaller than a predetermined value by repeatedly changing the value of the parameter till the index value calculated based on the azimuth and the ellipticity angle and also the azimuth and the ellipticity angle acquired by the acquiring unit becomes smaller than the predetermined value.

3. A calculation method by which a computer executes:
acquiring an azimuth and an ellipticity angle of a polarization plane of a laser beam passing through a plasma; and
calculating at least one of a magnetic field profile, an electron density profile and an electron temperature profile in the plasma on the basis of the azimuth and the ellipticity angle.

4. A calculation method by which a computer executes:
acquiring an azimuth and an ellipticity angle of a polarization plane of a laser beam passing through a plasma; and
simulating the azimuth and the ellipticity angle of the polarization plane of the laser beam passing through the plasma on the basis of a predetermined mathematical model containing a predetermined parameter and calculating at least one of a magnetic field profile, an electron density profile and an electron temperature profile in the plasma on the basis of a value of the parameter when an index value is smaller than a predetermined value by repeatedly changing the value of the parameter till the index value calculated based on the azimuth and the ellipticity angle and also the azimuth and the ellipticity angle acquired by the acquiring unit becomes smaller than the predetermined value.

5. A non-transitory computer readable storage medium storing a calculation program making a computer execute:
acquiring an azimuth and an ellipticity angle of a polarization plane of a laser beam passing through a plasma; and
calculating at least one of a magnetic field profile, an electron density profile and an electron temperature profile in the plasma on the basis of the azimuth and the ellipticity angle.

6. Anon-transitory computer readable storage medium storing a calculation program making a computer execute:
acquiring an azimuth and an ellipticity angle of a polarization plane of a laser beam passing through a plasma; and
simulating the azimuth and the ellipticity angle of the polarization plane of the laser beam passing through the plasma on the basis of a predetermined mathematical model containing a predetermined parameter and calculating at least one of a magnetic field profile, an electron density profile and an electron temperature profile in the plasma on the basis of a value of the parameter when an index value is smaller than a predetermined value by repeatedly changing the value of the parameter till the index value calculated based on the azimuth and the ellipticity angle and also the azimuth and the ellipticity angle acquired by the acquiring unit becomes smaller than the predetermined value.
